(19) United States
(12) Patent Application Publication
(10) Pub. No.: US 2026/0260799 A1
(43) Pub. Date: Sep. 3, 2026

(54) Systems and Methods for an Actuator Cover With an Integrated Sensor

(71) Applicant: HUSCO Automotive Holdings LLC, Waukesha, WI (US)

(72) Inventors: Trevor Wynkoop, Milwaukee, WI (US); Matthew Pellmann, Summit, WI (US); Matthew Koehler, Burlington, WI (US)

(21) Appl. No.: 19/489,208

(22) PCT Filed: May 31, 2024
(86) PCT No.: PCT/US2024/032101

§ 371 Date: Dec. 1, 2025

Related U.S. Application Data
(60) Provisional application No. 63/470,335, filed on Jun. 1, 2023.

(51) Int. Cl. H01F 7/128; H01F 7/06; H01F 7/08; H05K 5/03

(52) U.S. Cl. CPC H01F 7/128; H01F 7/064; H01F 7/081; H05K 5/03; H01F 2007/086

(57) ABSTRACT

An actuator cover for a solenoid actuator includes a cover body defining an interior cavity configured to receive a solenoid actuator. An opening at a first end of the cover body is configured to receive the solenoid actuator therethrough. A position sensor is disposed within the interior cavity of the cover body, external to the solenoid actuator. The position sensor is configured to sense a position of an actuator pin movable by the solenoid actuator.

### CROSS-REFERENCE TO RELATED APPLICATION

This application claims the benefit of U.S. Provisional Patent Application No. 63/470,335, filed on Jun. 1, 2023, which is incorporated herein by reference in its entirety.

### BACKGROUND

Solenoids typically include a wire coil arranged around a moveable armature. When a current is applied to the wire coil, a magnetic field is generated that can actuate (i.e., move) the armature between positions.

### SUMMARY OF THE INVENTION

The present disclosure provides an actuator housing that includes an integrated position sensor for determining a position of an actuator (e.g., a movable portion of a solenoid, motor, or other electromagnetic actuator) disposed within the actuator housing.

According to one aspect of the disclosure, a cover for an electromagnetic actuator can include a cover body defining an interior cavity configured to receive the electromagnetic actuator therein. An opening at a first end of the cover body can be configured to receive the electromagnetic actuator therethrough. A sensor can be disposed within the interior cavity of the cover body, external to the electromagnetic actuator. The sensor can be configured to sense a location of a movable portion of the electromagnetic actuator.

In some examples, the cover can further include an electrical connector formed on an exterior surface of the cover body. The electrical connector can include a first pin. A first electrical contact can extend from an interior surface of the cover body into the interior cavity. The first electrical contact can be in electrical communication with the first pin. The first electrical contact can be configured to engage with a first electrical terminal arranged on the electromagnetic actuator, such that electrical signals are transferable between the electrical connector and the electromagnetic actuator. The first electrical contact can be in electrical communication with the first pin by a first lead that extends through a sidewall of the cover body. In some cases, the electrical connector can further include a second pin that is in electrical communication with the sensor by a second lead extending through the sidewall of the cover body. The cover body can comprise plastic and the sensor, the first lead, and the second lead can be encapsulated by the plastic that forms at least a portion of the cover body.

In some examples, the cover can further include a mounting flange extending around a perimeter of the opening. The mounting flange can include a seal groove extending around the perimeter of the opening, the seal groove configured to receive a seal. The mounting flange can include a fastening aperture extending through the mounting flange. The fastening aperture can include a compression limiter inserted therein.

In some examples, the cover can further include an alignment rib extending from an interior surface of the cover body into the interior cavity. The alignment rib can be configured to engage an exterior surface of a housing of the electromagnetic actuator, such that the movable portion of the electromagnetic actuator is in alignment with the sensor. In some cases, the alignment rib is one of a plurality of alignment ribs and each alignment rib of the plurality of alignment ribs can be circumferentially separated from an adjacent alignment rib.

In some examples, the electromagnetic actuator can be configured as a solenoid actuator and the movable portion can be configured as a pin. The sensor can be configured as at least one of a position sensor that senses a position of the pin or an orientation sensor that senses an orientation of the pin. In some cases, the sensor is a Hall Effect sensor.

According to another aspect of the disclosure, an actuator assembly can include a solenoid actuator and a cover. The solenoid actuator can include a solenoid housing defining a first housing end and a second housing end and a wire coil arranged within the solenoid housing. An armature can be slidably received within the solenoid housing and can be selectively movable in response to a current applied to the wire coil. A pin can be coupled to the armature and can define a pin axis, such that the pin moves axially with the armature along the pin axis. The cover can include a cover body defining an interior cavity receiving the solenoid actuator therein and an opening configured to receive the solenoid actuator therethrough. A sensor can be disposed within the interior cavity of the cover body, external to the solenoid housing of the solenoid actuator. The sensor can be configured to detect a location of the pin.

In some examples, the pin can include a sensing end and an actuation end axially opposite the sensing end. The sensing end of the pin can extend axially through the first housing end of the solenoid housing, into the interior cavity, such that the sensing end is arranged adjacent to the sensor. The pin can be configured as a pin assembly. The actuation end of the pin can extend axially through the second housing end of the solenoid housing, into the opening of the cover. In some cases, the cover can further include an electrical connector formed on an exterior surface of the cover body. The electrical connector can include a first pin, a second pin, a third pin, and a fourth pin. The cover can further include a first electrical contact and a second electrical contact extending from an interior surface of the cover body into the interior cavity. The first and second electrical contacts can be in electrical communication with the first pin and the second pin of the electrical connector, respectively.

In some examples, the solenoid actuator can further include a first electrical terminal and a second electrical terminal, which are external to the solenoid housing and in electrical communication with the wire coil. The first electrical contact and the second electrical contact can be configured to engage with the first electrical terminal and the second electrical terminal, respectively, when the solenoid actuator is inserted into the interior cavity of the cover, such that electrical signals are transferable between the electrical connector of the cover and the wire coil of the solenoid actuator. The first electrical contact and the second electrical contact can be in electrical communication with the first pin and the second pin by a first lead and a second lead, respectively. The sensor can be in electrical communication with the third pin and the fourth pin by a third lead and a fourth lead, respectively. The first lead, the second lead, the third lead, and the fourth lead can extend through a sidewall of the cover body. The cover body can comprise plastic and the sensor, the first lead, the second lead, the third lead, and the fourth lead can be encapsulated within the sidewall by plastic that forms at least a portion of the cover body.

In some examples, the actuator assembly can further include a plurality of alignment ribs extending from an interior surface of the cover body into the interior cavity. Each of the plurality of alignment ribs can extend into the interior cavity of the cover to contact an exterior surface of the solenoid housing of the solenoid actuator to position the pin of the solenoid actuator within a predetermined radial distance from the sensor within the interior cavity of the cover. In some cases, the sensor can be at least one of a position sensor that is configured to sense a position of an actuator pin movable by the solenoid actuator or an orientation sensor that is configured to sense an orientation of an actuator pin movable by the solenoid actuator.

According to yet another aspect of the disclosure, a method of sensing a position of a pin movable by a solenoid actuator includes detecting, by a position sensor arranged within a cover body of an actuator cover, the position of the pin extending from a housing of the solenoid actuator into an interior cavity defined by the actuator cover. The interior cavity of the actuator cover houses at least a portion of the solenoid actuator.

In some examples, detecting the position of the pin includes detecting an orientation of the pin. The cover body can comprise plastic and the position sensor can be encapsulated by an epoxy material to secure the position sensor partially within the cover body.

According to still another aspect of the disclosure, a cover for an electromagnetic actuator can include a cover body defining an interior cavity configured to receive the electromagnetic actuator therein. An opening at a first end of the cover body can be configured to receive the electromagnetic actuator therethrough. A sensor can be disposed within the interior cavity of the cover body, external to the electromagnetic actuator. The sensor can be configured to sense a location of an actuator pin movable by the electromagnetic actuator. In some examples, the electromagnetic actuator can be a solenoid actuator.

According to yet another aspect of the disclosure, a cover for a solenoid actuator can include a cover body defining an interior cavity configured to receive a solenoid actuator therein. An opening at a first end of the cover body can be configured to receive the solenoid actuator therethrough. An electrical connector can be formed on an exterior surface of the cover body and can include one or more electrical pins.

In some examples, the cover can further include a sensor disposed within the interior cavity of the cover body and external to the solenoid actuator. The sensor can be configured to sense a location of an actuator pin movable by the solenoid actuator.

According to still another aspect of the disclosure, a cover for a solenoid actuator can include a cover body defining an interior cavity configured to receive a solenoid actuator therein. An opening at a first end of the cover body can be configured to receive the solenoid actuator therethrough. A sensor can be disposed within the interior cavity of the cover body, external to the solenoid actuator. The sensor can be configured to sense a location of an actuated component of the solenoid actuator movable by the solenoid actuator.

In some examples, the actuated component of the solenoid actuator can be an actuator pin of the solenoid actuator. The actuated component of the solenoid actuator can be an armature of the solenoid actuator or the actuated component of the solenoid actuator can be a plunger of the solenoid actuator.

The foregoing and other aspects and advantages of the disclosure will appear from the following description. In the description, reference is made to the accompanying drawings which form a part hereof, and in which there is shown by way of illustration a preferred configuration of the disclosure. Such configuration does not necessarily represent the full scope of the disclosure, however, and reference is made therefore to the claims and herein for interpreting the scope of the disclosure.

### DESCRIPTION OF DRAWINGS

The invention will be better understood and features, aspects and advantages other than those set forth above will become apparent when consideration is given to the following detailed description thereof. Such detailed description makes reference to the following drawings.

FIG. 1 is an exploded perspective view of an actuator assembly including an actuator cover and a solenoid actuator according to one aspect of the present disclosure.

FIG. 2 is a cross-section view of the actuator assembly of FIG. 1.

FIG. 3 is a bottom plan view of the actuator cover of FIG. 1 with the solenoid actuator removed.

FIG. 4 is a bottom plan view of the actuator assembly of FIG. 1 with the solenoid actuator positioned within the actuator cover.

FIG. 5 is a cross-section view of the actuator assembly of FIG. 1 taken along line 5-5 in FIG. 4.

FIG. 6 is a cross-section view of the actuator assembly of FIG. 1 taken along line 6-6 of FIG. 5.

FIG. 7 is a top plan view of the actuator cover of FIG. 1.

FIG. 8 is a partial cross-section view of the actuator assembly of FIG. 1 taken along line 8-8 of FIG. 4.

### DETAILED DESCRIPTION OF THE INVENTION

Before any aspects of the present disclosure are explained in detail, it is to be understood that the present disclosure is not limited in its application to the details of construction and the arrangement of components set forth in the following description or illustrated in the following drawings. The present disclosure is capable of other configurations and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The following discussion is presented to enable a person skilled in the art to make and use aspects of the present disclosure. Various modifications to the illustrated configurations will be readily apparent to those skilled in the art, and the generic principles herein can be applied to other configurations and applications without departing from aspects of the present disclosure. Thus, aspects of the present disclosure are not intended to be limited to configurations shown but are to be accorded the widest scope consistent with the principles and features disclosed herein. The following detailed description is to be read with reference to the figures, in which like elements in different figures have like reference numerals. The figures, which are not necessarily to scale, depict selected configurations and are not intended to limit the scope of the present disclosure. Skilled artisans will recognize the non-limiting examples provided herein have many useful alternatives and fall within the scope of the present disclosure.

The use herein of the term “axial” and variations thereof refers to a direction that extends generally along an axis of symmetry, a central axis, or an elongate direction of a particular component or system. For example, an axially-extending structure of a component may extend generally along a direction that is parallel with respect to an axis of symmetry or an elongate direction of that component. Similarly, the use herein of the term “radial” and variations thereof refers to directions that are generally perpendicular with respect to a corresponding axial direction. For example, a radially extending structure of a component may generally extend at least partly along a direction that is perpendicular with respect to a longitudinal or central axis of that component. The use herein of the term “circumferential” and variations thereof refers to a direction that extends generally around a circumference or periphery of an object, around an axis of symmetry, around a central axis, or around an elongate direction of a particular component or system.

Sensors (e.g., position, orientation, angle, or other types of sensors) can be used for providing feedback about a position and/or orientation of a movable or actuatable component of an actuator (e.g., an armature, a pin of a solenoid actuator, a spindle of a motor, a plunger, etc.). For example, position sensors may be used to provide feedback about the position of a solenoid armature. In another example, orientation sensors may be used to provide feedback about the orientation of the solenoid armature. In yet another example, a combination of sensors, such as a position sensor and an orientation sensor, may be used to provide feedback about the position and orientation of the solenoid armature. In conventional applications, sensors can form part of the solenoid actuator, increasing the complexity of the construction of the solenoid actuator or solenoid housing design, leading to higher manufacturing costs. As will be described below in greater detail, the present disclosure provides an actuator cover that receives a solenoid actuator therein. The actuator cover includes a sensor (e.g., a position sensor or another type of sensor) arranged within the cover, such that the sensor is external to the solenoid actuator. This arrangement can reduce the complexity of the solenoid actuator design.

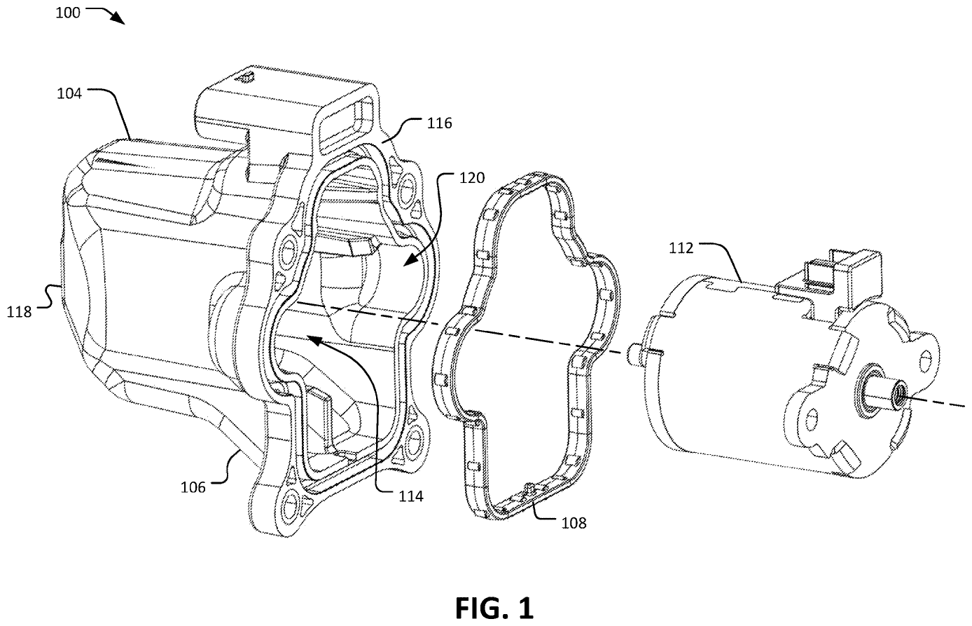

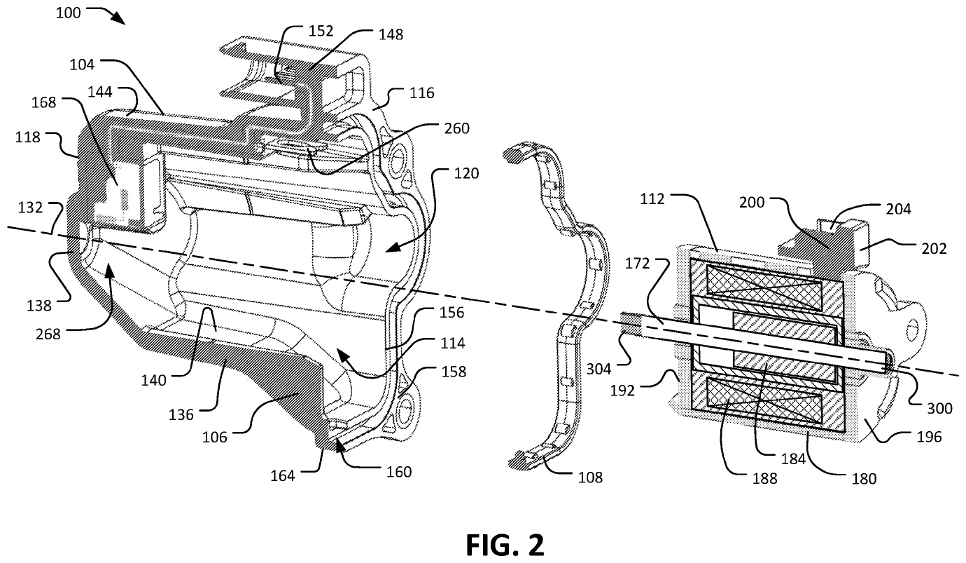

FIGS. 1 and 2 illustrate a non-limiting example of an actuator assembly 100. The actuator assembly 100 can include an actuator cover (e.g., a cover) 104, a seal 108, and an actuator 112. As illustrated, the actuator 112 is configured as a solenoid actuator, but may also be any other type of actuator, for example, an electromagnetic actuator configured as any of a motor, linear actuator, rotary actuator, etc. The actuator cover 104 includes a cover body 106 defining an interior cavity 114 extending from a first end 116 to an opposing second end 118 of the cover body 106. The cover body 106 is configured to at least partially enclose the solenoid actuator 112. The actuator cover 104 further defines an opening 120 arranged at the first end 116 of the cover body 106. The opening 120 is configured to provide access to the interior cavity 114. The opening 120 is configured to receive the solenoid actuator 112 therethrough to arrange the solenoid actuator 112 within the interior cavity 114 of the actuator cover 104. The cover body 106 defines a sidewall 136 extending from the opening 120 at the first end 116 to a base wall 138 forming the closed second end 118. The sidewall 136 and base wall 138 extend between an interior surface 140 and an exterior surface 144 of the cover body 106. The first end 116 of the illustrated non-limiting example forms a generally flat surface. However, in some aspects, the first end 116 may be irregular, wavy, and/or uneven in shape.

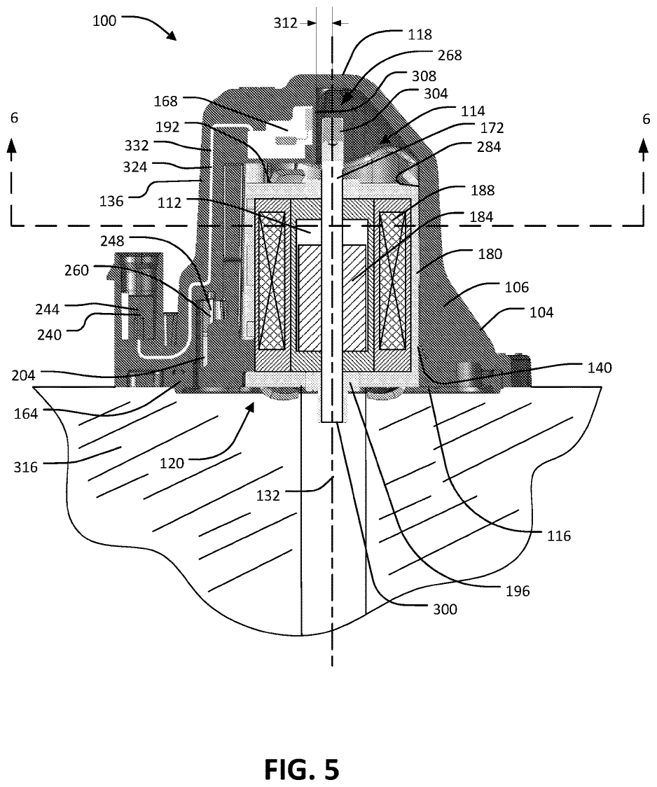

In the illustrated non-limiting example of FIG. 2, the opening 120 defines a perimeter 156 extending therearound. The cover body 106 further includes a mounting flange 164 located at the first end 116. The mounting flange 164 may include a mounting surface 158 extending around the perimeter 156 of the opening 120. The mounting surface 158 is configured to engage with a component 316 (e.g., a support structure, see FIG. 5) when the actuator assembly 100 is coupled to the component 316 (see, e.g., FIG. 5). The mounting flange 164 includes a seal groove 160 surrounding the perimeter 156 to receive the seal 108. The seal 108 is configured to seal a portion of the first end 116 of the actuator cover 104 when the actuator cover 104 is coupled to the component 316. In the illustrated non-limiting example, the seal groove 160 wraps around the entire periphery of the opening 120. However, in some aspects, the seal groove 160 may wrap around a portion of the perimeter 156 of the opening 120 to at least partially surround the opening 120. In the illustrated non-limiting example, the seal groove 160 is configured as a recess in the mounting surface 158. However, in some aspects, the seal groove 160 can be configured as an embossment and/or raised surface extending from the mounting surface 158, which is configured to receive and/or retain the seal 108. In some non-limiting examples, the seal groove 160 can be configured as a press in place (“PIP”) seal groove, and be configured to receive a PIP seal, although other configurations are possible. In some examples, a gasket and/or other sealing material (e.g., sealant) may be included on the mounting surface 158 in lieu of the seal groove 160 and seal 108.

Still referring to the illustrated non-limiting example of FIG. 2, the solenoid actuator 112 can include a pin 172 (e.g., an armature pin) which is moveable via an armature 184. The armature 184 is surrounded by one or more wire coils 188 configured to generate a varying magnetic field upon the receiving an electric current. Based on the current flow, the wire coils 188 may induce movement in the armature 184, which in turn may actuate the pin 172 between one or more positions. The wire coil 188 and at least a portion of the pin 172 are surrounded by a solenoid housing 180. In the illustrated non-limiting example, the solenoid housing 180 is cylindrically shaped. However, in other non-limiting examples, the solenoid housing 180 can define a different geometric shape, such as square, rectangular, polygonal, etc., including asymmetric and/or symmetric shapes. The solenoid housing 180 includes a first housing end 192 that is opposite a second housing end 196. A pin axis 132 extends through the centerline (e.g., a central axis) of the pin 172 to extend between the first housing end 192 and the second housing end 196).

The solenoid actuator 112 can further include a first electrical terminal 200 and a second electrical terminal 204 coupled to a terminal housing 202. The terminal housing 202 is coupled to the solenoid housing 180. The first electrical terminal 200 and the second electrical terminal 204 are in electrical communication with the wire coil 188. The first electrical terminal 200 and the second electrical terminal 204 are configured to receive an electrical signal which is then communicated to the wire coil 188 to activate the wire coil 188. When the wire coil 188 is activated with the electrical signal, the solenoid actuator 112 moves the armature 184 axially along the pin axis 132 between a first position and a second position. In some examples, the electric signal may be in the form of an increased voltage and/or an increased current. The electrical signal may include multiple electrical signals that can be measured as current signals or commands, voltage signals or commands, pulse width modulation (PWM) signals, and/or feedback signals.

In the illustrated non-limiting example of FIG. 2, the armature 184 is in the first position. In some aspects, the pin 172 is directly coupled to the armature 184, and the armature 184 and the pin 172 move together along the pin axis 132 between the first position and the second position.

Still referring to the illustrated example of FIG. 2, a sensor 168 is disposed within the interior cavity 114 of the cover body 106. The sensor 168 can be configured to detect movement (e.g., a change in position, orientation, etc.) of a moveable portion of an actuator (e.g., an armature, a pin of a solenoid, a motor spindle, etc.). In one non-limiting example, the sensor 168 can be a position sensor configured to detect a position of the pin 172. In another non-limiting example, the sensor 168 can be an orientation sensor configured to detect an orientation of the pin 172. In yet another example, the sensor 168 is provided as plurality of sensors, such as a position sensor and an orientation sensor, which may be used to provide feedback about the position and orientation of the pin 172. As will be described below in greater detail, the sensor 168 is configured to sense a position of the armature pin 172 of the solenoid actuator 112. In some aspects, the sensor 168 can include a Hall Effect sensor, a reed switch, an inductive/capacitive proximity senor, a linear variable differential transformer, an optical sensor, a magnetic encoder, a potentiometer, a piezoelectric sensor, a fiber optic sensor and/or another type of sensor.

In the illustrated non-limiting example, the sensor 168 is coupled to the interior surface 140 of the cover body 106 at the second end 118 thereof. In particular, the sensor 168 is encapsulated (e.g., overmolded) onto the sidewall 136 of the cover body 106 to secure the sensor 168 to the cover body 106. In another non-limiting example, the sensor 168 is placed within a portion of the cover body 106 and then potted (e.g., covered) by an epoxy and/or resin material. In other non-limiting examples, the sensor 168 can be coupled to the actuator cover 104 by a fastener and/or adhesive. Alternatively, the interior surface 140 may include a sensor retainer configured to retain the sensor 168 adjacent the interior surface 140 of the cover body 106. Since the sensor 168 is disposed within the interior cavity 114 of the cover body 106 of the actuator cover 104, the sensor 168 is external to the solenoid housing 180 of the solenoid actuator 112.

The pin 172 can include a sensing end 304 opposite an actuation end 300. The actuation end 300 is arranged proximate to the second housing end 196 and is configured to engage an actuation element to actuate the actuation element (e.g., to move a gear of a wheel end disconnect, to move a spool of a valve, etc.). The actuation end 300 can extend axially through the second housing end 196 of the solenoid housing 180, through the opening 120 of the actuator cover 104 and axially away from the second housing end 196. The sensing end 304 is arranged proximate to the first housing end 192. The interior cavity 114 includes a pin recess 268 defining open space adjacent the sensor 168. The pin recess 268 is configured to receive the pin 172 as the pin 172 is moving between positions (e.g., as the pin 172 moves into the first stable position). In some examples, the pin 172 may be provided as a pin assembly including a magnetic and/or ferromagnetic material that can be sensed by the sensor 168, such as a Hall Effect sensor.

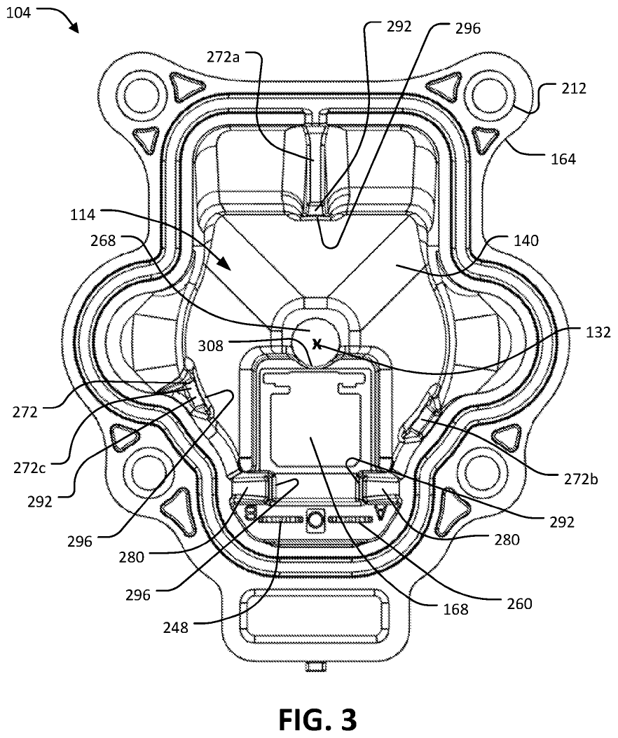

Referring now to FIGS. 3-6, the cover body 106 can include one or more radial alignment ribs 272. The radial alignment ribs 272 (e.g., a first radial alignment rib 272a, a second radial alignment rib 272b, and a third radial alignment rib 272c) are configured to contact an exterior surface 284 of the solenoid housing 180 to radially align the actuator cover 104 and the solenoid actuator 112. For example, the radial alignment ribs 272 can be configured to maintain alignment of the actuator cover 104 and the solenoid actuator 112 with respect to the pin axis 132 as the solenoid housing 180 is inserted into the interior cavity 114. In this way, the pin 172 of the solenoid actuator 112 can be positioned in alignment with the sensor 168 in the cover body 106. For example, as best illustrated in FIG. 5, the sensing end 304 of the pin 172 is configured to move adjacent to a sensing surface 308 of the sensor 168. The radial alignment ribs 272 are configured to position the solenoid actuator 112, and thereby the pin 172, within a predetermined radial distance 312 of the sensor 168. For example, the radial alignment ribs 272 are circumferentially spaced or separated from one another on the cover body 106, such that each alignment rib (e.g., a first alignment rib 272a) is circumferentially separated from adjacent alignment ribs (e.g., the second and third alignment ribs 272b, 272c). The radial distance 312 is defined as the distance between the pin axis 132 of the solenoid actuator 112 and the sensing surface 308. The radial distance 312 is selected such that the sensor 168 can detect the position of the sensing end 304 of the pin 172. The sensing surface 308 of the sensor 168 can be curved in an arc around the pin axis 132. In the illustrated non-limiting example, the sensing surface 308 is concavely shaped relative to the pin axis 132. In other non-limiting examples, the sensing surface 308 may be a flat, wavy, convex, and/or concave surface.

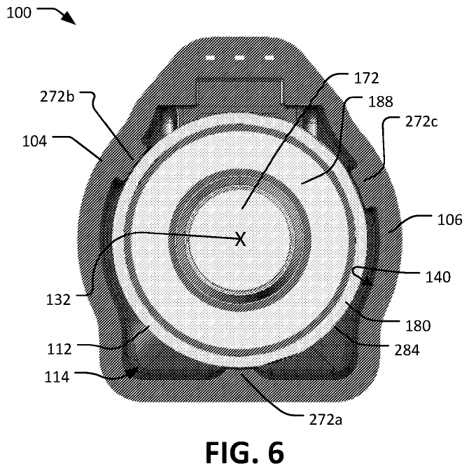

As best illustrated in FIG. 6, the radial alignment ribs 272 extend radially inward (e.g., toward the pin axis 132) from an interior surface 140 of the cover body 106 to contact the exterior surface 284 of the solenoid housing 180. In the illustrated non-limiting example, the cover body 106 includes three radial alignment ribs 272 (i.e., the first radial alignment rib 272a, the second radial alignment rib 272b, and the third radial alignment rib 272c). In other non-limiting examples, the cover body 106 can include more or less than three radial alignment ribs (e.g., one alignment rib, four alignment ribs five alignment ribs, 7 alignment ribs, etc.).

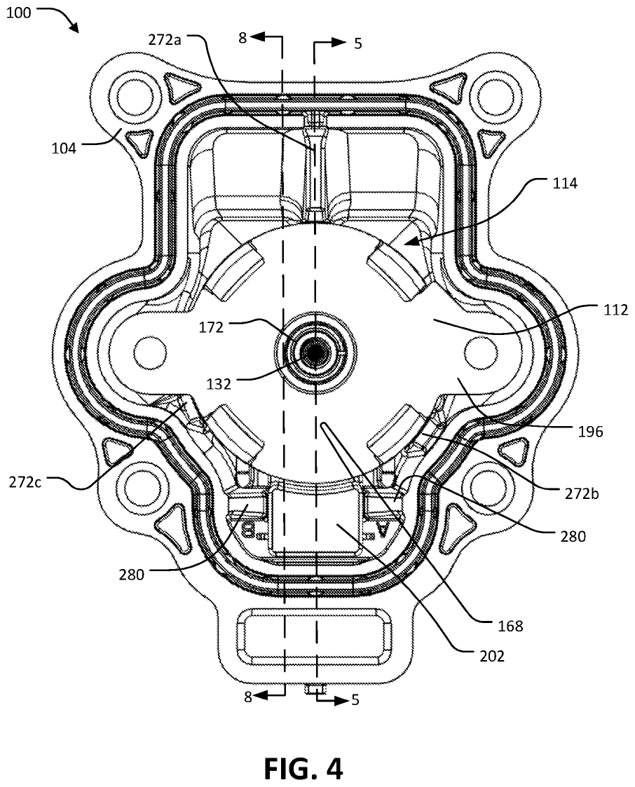

As illustrated in FIG. 4, the cover body 106 can also include one or more circumferential alignment ribs 280. The circumferential alignment ribs 280 are configured to contact the terminal housing 202 that is connected to the solenoid housing 180. For example, the circumferential alignment ribs 280 are configured to control the circumferential orientation of the solenoid actuator 112 with respect to the pin axis 132 as the solenoid actuator 112 is inserted into the interior cavity 114. In this way, rotation of the solenoid actuator 112 relative to the pin axis 132 is prevented after the solenoid actuator 112 is inserted in the interior cavity 114.

Each of the radial alignment ribs 272, and circumferential alignment ribs 280 extend from the first end 116 toward the second end 118 along the interior surface 140 of the cover body 106 and along a direction that is parallel with respect to the pin axis 132. The radial alignment ribs 272 and circumferential alignment ribs 280 each include a lead surface 292 that is angled with respect to an engagement surface 296. The engagement surface 296 is configured to contact and engage at least one of the solenoid housing 180 or the terminal housing 202. In one example, the lead surface 292 may be chamfered and/or beveled. The lead surface 292 is configured to guide the solenoid housing 180 and/or the terminal housing 202 into engagement with the engagement surface 296 of the radial alignment ribs 272 and circumferential alignment ribs 280 in order to provide radial and circumferential stability for the solenoid actuator 112 when inserted into the interior cavity 114.

The radial alignment ribs 272 and circumferential alignment ribs 280 are used in conjunction to radially and circumferentially control the orientation of the solenoid housing 180 and/or terminal housing 202 with respect to the pin axis 132 as the solenoid housing 180 is inserted into the interior cavity 114. In this way, the position of the pin 172 with respect to the sensor 168 can be better controlled, for example to reduce tolerance about a predetermined and/or standardized value, as may ensure that the pin 172 is positioned within a predetermined distance (e.g., the radial distance 312) from the sensor 168 to allow the sensor 168 to detect the sensing end 304 of the pin 172. Further, the position of the terminal housing 202 can be aligned with electrical contacts in the cover body 106, as will be further described below.

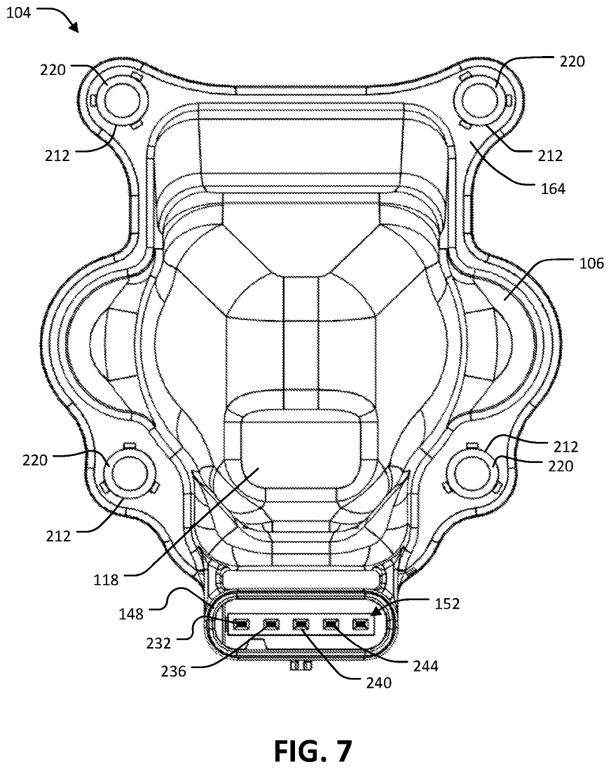

In the illustrated non-limiting example of FIG. 7, the mounting flange 164 of the actuator cover 104 can include one or more fastening apertures 212. Each of the fastening apertures 212 are configured to receive a compression limiter 220 (e.g., a sleeve). The compression limiter 220 is configured to prevent over-tightening of the fasteners received within the fastening apertures 212. The fastening apertures 212 and compression limiter 220 provide a way to facilitate mounting the actuator cover 104 to another object, such as, for example, the component 316 of FIG. 5.

Referring now to FIGS. 2, 3, and 5, the cover body 106 can include at least one electrical contact configured to engage with the electrical terminals 200, 204 of the solenoid actuator 112. In the illustrated non-limiting example, the cover body 106 includes a first electrical contact 248 and a second electrical contact 260. The first electrical contact 248 and the second electrical contact 260 are configured to engage the first electrical terminal 200 and the second electrical terminal 204 of the solenoid actuator 112, respectively. When the solenoid actuator 112 is inserted into the interior cavity 114 of the actuator cover 104, electrical signals are transferable between an electrical connector 148 included in the actuator cover 104 and the wire coil 188 of the solenoid actuator 112. In one non-limiting example, the first electrical contact 248 and the second electrical contact 260 may each be configured as a blade and/or blade-shaped. The electrical contacts 248, 260 may each include a slot that extends into the blade to receive the electrical terminals 200, 204 therein. In another non-limiting example, the first electrical contact 248 and the second electrical contact 260 may each include a flat surface that is configured to contact a corresponding flat surface of the first electrical terminal 200 and/or the second electrical terminal 204.

In the illustrated non-limiting examples in FIGS. 2 and 7, the actuator cover 104 further includes an electrical connector 148 coupled to the exterior surface 144 of the cover body 106. In the illustrated non-limiting example, the electrical connector 148 is integrally formed with the cover body 106. The electrical connector 148 can include one or more electrical pins 152 that are configured to communicate electrical signals to the solenoid actuator 112 and/or the sensor 168. In some non-limiting examples, the electrical connector 148 can be configured as a United States Council for Automotive Research (USCAR) electrical connector, or other standardized connector type, although other configurations are also possible. The electrical pins 152 can include a first pin 232, a second pin 236, a third pin 240, and a fourth pin 244. However, in some non-limiting examples, the electrical connector 148 may have more or less than four electrical pins 152. In one non-limiting example, the electrical connector 148 may include five (5) pins, with two (2) pins used for an H-bridge for actuator controls (e.g., for bidirectional actuator movement) and three (3) pins used for regulated power/ground sensor output.

In the illustrated non-limiting example, the electrical connector 148 is arranged adjacent to the first end 116 of the cover body 106. An open end of the electrical connector 148 faces toward the second end 118 of the cover body 106. In the illustrated non-limiting example, the electrical pins 152 extend away from the first end 116 of the cover body 106 toward the second end 118. However, in some non-limiting examples, the electrical connector 148 can be arranged in other orientations.

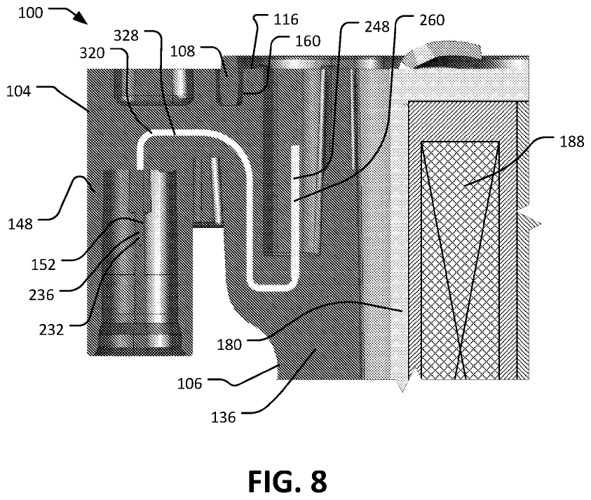

In the illustrated non-limiting example of FIG. 8, the first pin 232 is coupled to a first lead 328, which is coupled to the first electrical contact 248 of the actuator cover 104. The second pin 236 is coupled to a second lead 320, which is coupled to the second electrical contact 260. As previously discussed, the first electrical contact 248 and the second electrical contact 260 are configured to engage the first electrical terminal 200 and the second electrical terminal 204 of the solenoid actuator 112 when the solenoid actuator 112 is inserted into the interior cavity 114 of the actuator cover 104. In this way, electrical communication can be provided between the electrical connector 148 on the cover body 106 and solenoid actuator 112.

In the illustrated non-limiting example of FIG. 5, the third pin 240 is coupled to a third lead 324 that extends through the sidewall 136 of the cover body 106 to form a connection with the sensor 168. The fourth pin 244 is coupled to a fourth lead 332 that extends through the sidewall 136 of the cover body 106 to form a connection with the sensor 168, thereby establishing electronic communication between the electrical connector 148 on the cover body 106 and the sensor 168 arranged within the interior cavity 114. Electronic communication between the electrical connector 148 and the sensor 168 enables the sensor 168 to receive an electric signal (e.g., a variable voltage and/or current signal) that activates the sensor 168. Alternatively, electronic communication between the electrical connector 148 and the sensor 168 enables the electrical connector 148 to receive sense and/or location data from the sensor 168 indicating detection and/or location (e.g., position and/or orientation) of the sensing end 304 of the pin 172. In some aspects, the sensor 168, the first lead 328, the second lead 320, the third lead 324, and the fourth lead 332 are encapsulated (e.g., overmolded, potted, etc.), within the sidewall 136 via plastic forming at least a portion of the cover body 106.

As used in the claims, the phrase “at least one of A, B, and C” means at least one of A, at least one of B, and/or at least one of C, or any one of A, B, or C or combination of A, B, or C. A, B, and C are elements of a list, and A, B, and C may be anything contained in the Specification.

Within this specification non-limiting examples have been described in a way which enables a clear and concise specification to be written, but it is intended and will be appreciated that embodiments may be variously combined or separated without parting from the invention. For example, it will be appreciated that all preferred features described herein are applicable to all aspects of the invention described herein.

Thus, while the invention has been described in connection with particular embodiments and examples, the invention is not necessarily so limited, and that numerous other embodiments, examples, uses, modifications and departures from the embodiments, examples and uses are intended to be encompassed by the claims attached hereto.

Various features and advantages of the invention are set forth in the following claims.

We claim:

1. A cover for an electromagnetic actuator, the cover comprising:
a cover body defining an interior cavity configured to receive the electromagnetic actuator therein;
an opening at a first end of the cover body configured to receive the electromagnetic actuator therethrough; and
a sensor disposed within the interior cavity of the cover body, external to the electromagnetic actuator, wherein the sensor is configured to sense a location of a movable portion of the electromagnetic actuator.

2. The cover of claim 1, further comprising an electrical connector formed on an exterior surface of the cover body, the electrical connector including a first pin.

3. The cover of claim 2, further comprising a first electrical contact extending from an interior surface of the cover body into the interior cavity, the first electrical contact being in electrical communication with the first pin.

4. The cover of claim 3, wherein the first electrical contact is configured to engage with a first electrical terminal arranged on the electromagnetic actuator, such that electrical signals are transferable between the electrical connector and the electromagnetic actuator.

5. The cover of claim 3, wherein the first electrical contact is in electrical communication with the first pin by a first lead extending through a sidewall of the cover body.

6. The cover of claim 5, wherein the electrical connector further includes a second pin, the second pin being in electrical communication with the sensor by a second lead extending through the sidewall of the cover body.

7. The cover of claim 6, wherein the cover body comprises plastic, and wherein the sensor, the first lead, and the second lead are encapsulated by plastic that forms at least a portion of the cover body.

8. The cover of claim 1, further comprising a mounting flange extending around a perimeter of the opening.

9. The cover of claim 8, wherein the mounting flange includes a seal groove extending around the perimeter of the opening, the seal groove configured to receive a seal.

10. The cover of claim 8, wherein the mounting flange includes a fastening aperture extending through the mounting flange.

11. The cover of claim 10, wherein the fastening aperture includes a compression limiter inserted therein.

12. The cover of claim 1, further comprising an alignment rib extending from an interior surface of the cover body into the interior cavity, wherein the alignment rib is configured to engage an exterior surface of a housing of the electromagnetic actuator, such that the movable portion of the electromagnetic actuator is in alignment with the sensor.

13. The cover of claim 12, wherein the alignment rib is one of a plurality of alignment ribs, and wherein each alignment rib of the plurality of alignment ribs is circumferentially separated from an adjacent alignment rib.

14. The cover of claim 1, wherein the electromagnetic actuator is configured as a solenoid actuator and the movable portion is configured as a pin, and
wherein the sensor is configured as at least one of a position sensor that senses a position of the pin or an orientation sensor that senses an orientation of the pin.

15. The cover of claim 1, wherein the sensor is a Hall Effect sensor.

16. An actuator assembly, comprising:
a solenoid actuator including:
a solenoid housing defining a first housing end and a second housing end;
a wire coil arranged within the solenoid housing;
an armature slidably received within the solenoid housing and selectively movable in response to a current applied to the wire coil;
a pin coupled to the armature, wherein the pin defines a pin axis, such that the pin moves axially with the armature along the pin axis; and
a cover including:
a cover body defining an interior cavity receiving the solenoid actuator therein;
an opening configured to receive the solenoid actuator therethrough; and
a sensor disposed within the interior cavity of the cover body, external to the solenoid housing of the solenoid actuator, wherein the sensor is configured to detect a location of the pin.

17. The actuator assembly of claim 16, wherein the pin includes a sensing end and an actuation end axially opposite the sensing end, and
wherein the sensing end of the pin extends axially through the first housing end of the solenoid housing, into the interior cavity, such that the sensing end is arranged adjacent to the sensor.

18. The actuator assembly of claim 16, wherein the pin is configured as a pin assembly.

19. The actuator assembly of claim 17, wherein the actuation end of the pin extends axially through the second housing end of the solenoid housing, into the opening of the cover.

20. The actuator assembly of claim 16, wherein the cover further includes an electrical connector formed on an exterior surface of the cover body, the electrical connector including a first pin, a second pin, a third pin, and a fourth pin.

21. The actuator assembly of claim 20, wherein the cover further includes a first electrical contact and a second electrical contact extending from an interior surface of the cover body into the interior cavity, and
wherein the first and second electrical contacts are in electrical communication with the first pin and the second pin of the electrical connector, respectively.

22. The actuator assembly of claim 21, wherein the solenoid actuator further includes a first electrical terminal and a second electrical terminal, external to the solenoid housing and in electrical communication with the wire coil,
wherein the first electrical contact and the second electrical contact are configured to engage with the first electrical terminal and the second electrical terminal, respectively, when the solenoid actuator is inserted into the interior cavity of the cover, such that electrical signals are transferable between the electrical connector of the cover and the wire coil of the solenoid actuator.

23. The actuator assembly of claim 21, wherein the first electrical contact and the second electrical contact are in electrical communication with the first pin and the second pin by a first lead and a second lead, respectively,
wherein the sensor is in electrical communication with the third pin and the fourth pin by a third lead and a fourth lead, respectively, and wherein the first lead, the second lead, the third lead, and the fourth lead extend through a sidewall of the cover body.

24. The actuator assembly of claim 23, wherein the cover body comprises plastic, and
wherein the sensor, the first lead, the second lead, the third lead, and the fourth lead are encapsulated, within the sidewall, by plastic that forms at least a portion of the cover body.

25. The actuator assembly of claim 16, further comprising a plurality of alignment ribs extending from an interior surface of the cover body into the interior cavity, wherein each of the plurality of alignment ribs extend into the interior cavity of the cover to contact an exterior surface of the solenoid housing of the solenoid actuator, to position the pin of the solenoid actuator within a predetermined radial distance from the sensor within the interior cavity of the cover.

26. The cover of claim 16, wherein the sensor is at least one of a position sensor that is configured to sense a position of an actuator pin movable by the solenoid actuator or an orientation sensor that is configured to sense an orientation of an actuator pin movable by the solenoid actuator.

27. A method of sensing a position of a pin movable by a solenoid actuator, the method comprising:
detecting, by a position sensor arranged within a cover body of an actuator cover, the position of the pin extending from a housing of the solenoid actuator into an interior cavity defined by the actuator cover,
wherein the interior cavity of the actuator cover houses at least a portion of the solenoid actuator.

28. The method of claim 27, wherein detecting the position of the pin includes detecting an orientation of the pin.

29. The method of claim 27, wherein the cover body comprises plastic, and
wherein the position sensor is encapsulated by an epoxy material to secure the position sensor partially within the cover body.

30. A cover for an electromagnetic actuator, the cover comprising:
a cover body defining an interior cavity configured to receive the electromagnetic actuator therein;
an opening at a first end of the cover body configured to receive the electromagnetic actuator therethrough; and
a sensor disposed within the interior cavity of the cover body, external to the electromagnetic actuator,
wherein the sensor is configured to sense a location of an actuator pin movable by the electromagnetic actuator.

31. The cover of claim 30, wherein the electromagnetic actuator is a solenoid actuator.

32. A cover for a solenoid actuator, comprising:
a cover body defining an interior cavity configured to receive a solenoid actuator therein;
an opening at a first end of the cover body configured to receive the solenoid actuator therethrough; and
an electrical connector formed on an exterior surface of the cover body, the electrical connector including an electrical pin.

33. The cover of claim 32, further comprising a sensor disposed within the interior cavity of the cover body and external to the solenoid actuator, the sensor configured to sense a location of an actuator pin movable by the solenoid actuator.

34. A cover for a solenoid actuator, comprising:
a cover body defining an interior cavity configured to receive a solenoid actuator therein;
an opening at a first end of the cover body configured to receive the solenoid actuator therethrough; and
a sensor disposed within the interior cavity of the cover body, external to the solenoid actuator,
wherein the sensor is configured to sense a location of an actuated component of the solenoid actuator movable by the solenoid actuator.

35. The cover of claim 34, wherein the actuated component of the solenoid actuator is an actuator pin of the solenoid actuator.

36. The cover of claim 34, wherein the actuated component of the solenoid actuator is an armature of the solenoid actuator.

37. The cover of claim 34, wherein the actuated component of the solenoid actuator is a plunger of the solenoid actuator.
